(19) United States
(12) Patent Application Publication
(10) Pub. No.: US 2026/0327858 A1
(43) Pub. Date: Oct. 22, 2026

(54) COMPOSITE NANOFIBER MEMBRANE, PIEZOELECTRIC MATERIAL COMPRISING THE SAME AND PREPARATION METHOD THEREOF

(71) Applicants: Kyungpook National University Industry-Academic Cooperation Foundation, Buk-gu (KR); SOFNT Inc., Yuseong-gu (KR)

(72) Inventors: Jang Ho PARK, Anyang-si (KR); Jin Hyun CHOI, Suseong-gu (KR); Sul A HAN, Seoul (KR)

(73) Assignees: Kyungpook National University Industry-Academic Cooperation Foundation, Buk-gu (KR); SOFNT Inc., Yuseong-gu (KR)

(21) Appl. No.: 19/639,384

(22) Filed: Apr. 6, 2026

(30) Foreign Application Priority Data
Apr. 11, 2025 (KR) 10-2025-0047546

(51) Int. Cl. D01D 5/00; B82Y 30/00; B82Y 40/00; D01F 1/09; D01F 8/16; H10N 30/092; H10N 30/098; H10N 30/85; H10N 30/857

(52) U.S. Cl. CPC D01D 5/0046; B82Y 30/00; B82Y 40/00; D01F 1/09; D01F 8/16; H10N 30/092; H10N 30/098; H10N 30/852; H10N 30/857; D10B 2321/042; D10B 2331/30; D10B 2403/0243

(57) ABSTRACT

The present disclosure relates to composite nanofiber membranes, piezoelectric materials comprising the same, and preparation methods thereof, and more particularly, to composite nanofiber membranes comprising nanofibers comprising a fluorine-based polymer and a crosslinked product of a siloxane-based polymer precursor; and a conductive nanomaterial dispersed in the nanofibers, and piezoelectric materials comprising the same and preparation methods thereof. It is expected that the composite nanofiber membranes manufactured according to an embodiment of the present disclosure and the piezoelectric materials comprising the same will be a promising material for applications in vehicles, robots, biosensors and audio devices.

### RELATED APPLICATIONS

This application claims the benefit of Korean patent application No. KR 10-2025-0047546, filed Apr. 11, 2025, which is herein incorporated by reference in its entirety for all purposes.

### TECHNICAL FIELD

The present disclosure relates to composite nanofiber membrane, piezoelectric material comprising the same, and preparation method thereof, and more particularly, to composite nanofiber membrane comprising nanofibers comprising a fluorine-based polymer and a crosslinked product of a siloxane-based polymer precursor; and a conductive nanomaterial dispersed in the nanofibers, piezoelectric material comprising the same, and preparation method thereof.

### BACKGROUND

With the development of flexible devices and wearable devices, there is a demand for materials of such devices with various characteristics including high mechanical strength, flexibility, electrical properties, sensitivity, thermal stability and lightweight. Attention is drawn to piezoelectric materials that meet these requirements, and the piezoelectric effect is used to convert mechanical signals into electrical signals in different types of electronic devices including smartphones, smartwatches, tablets and wireless earphones. When piezoelectric materials are subjected to external forces, positive and negative charges inside them are aligned, creating polarization, resulting in the generation of an electrical signal, which make them applicable to sensors, actuators or the like.

Piezoelectric materials may be largely classified into ceramics and polymers, and among ceramics, PbTiO₃ or PbZrO₃ having perovskite structures exhibit superior piezoelectricity. On the other hand, polymer-based piezoelectric materials such as polyvinylidene fluoride (PVDF) are gaining attention as a more suitable material for flexible and wearable devices than ceramic-based piezoelectric materials due to flexibility, ease of processing, safety, durability and light weight advantages.

PVDF is a representative piezoelectric polymer and has a, B and y phases according to the molecular structure, and β phase possesses strong piezoelectric properties due to the arrangement of hydrogen and fluorine. Accordingly, it is important to increase the proportion of B phase to improve the piezoelectricity of PVDF, and to do so, there are approaches using DMF solvent, metal nanoparticles and electrospinning (He, Z., et al. Polymers, 2021, 13 (2), 174).

For example, Korean Patent Publication No. 10-2024-0099881 is directed toward a method and apparatus for manufacturing a piezoelectric sensor made of PVDF-TrFE using electrospinning, and Korean Patent No. 10-1884701 is directed toward a PVDF nanofibrous membrane with high ratio of beta-phase, piezoelectric and ferroelectric properties and a method for manufacturing the same.

In particular, electrospinning is a technique that produces nanofibers by evaporating solvents using high-voltage electric fields, and the shape and diameter of fibers are determined by factors such as voltage, flow rate, collector, temperature and humidity. Compared to films, nanofiber membranes produced using electrospinning have high surface area-to-volume ratio, porosity, light weight and flexibility advantages, and may exhibit higher performance when applied to piezoelectric devices. In particular, piezoelectric devices using nanofiber membranes offer higher flexibility and surface area-to-volume ratio than the existing film-based devices, making them suitable for curved surface sensors or small devices, and their mechanical stability allows for long-term, stable operation.

Therefore, the inventors have studied various materials and production methods to develop nanofiber membranes and piezoelectric material with improved flexibility, conductivity and piezoelectricity based on fluorine-based polymer which is a representative piezoelectric polymer, and based on the findings, they have completed the present disclosure.

### SUMMARY OF THE INVENTION

The present disclosure is developed to address the above-described problems, and therefore the present disclosure is directed to providing nanofiber membranes and piezoelectric materials with improved flexibility, conductivity and piezoelectricity based on fluorine-based polymer which is a representative piezoelectric polymer.

To achieve the above-described objectives, the present disclosure provides composite nanofiber membranes comprising nanofibers comprising a fluorine-based polymer and a crosslinked product of a siloxane-based polymer precursor; and a conductive nanomaterial dispersed in the nanofibers.

In the composite nanofiber membranes according to the present disclosure, the fluorine-based polymer may include β-phase polyvinylidene fluoride (PVDF) having piezoelectricity, and the conductive nanomaterial may include at least one selected from silver nanoparticles (AgNPs) or MXene.

### Advantageous Effects

As described above, the key advantage of the present disclosure is characterized by the nanofiber membrane and piezoelectric material with improved flexibility, conductivity and piezoelectricity.

It is expected that the composite nanofiber membrane produced according to an embodiment of the present disclosure, and the piezoelectric material comprising the same will be a promising material for applications in flexible and wearable devices as well as medical sensors, biosensors and audio devices.

The features and advantages described herein are not all-inclusive and, in particular, many additional features and advantages will be apparent to one of ordinary skill in the art in view of the drawings, specification, and claims. Moreover, it should be noted that the language used in the specification has been principally selected for readability and instructional purposes, and not to limit the scope of the inventive subject matter.

### BRIEF DESCRIPTION OF THE DRAWINGS

FIG. 1 shows chemical structures of a-phase,-phase and γ-phase of polyvinylidene fluoride (PVDF).

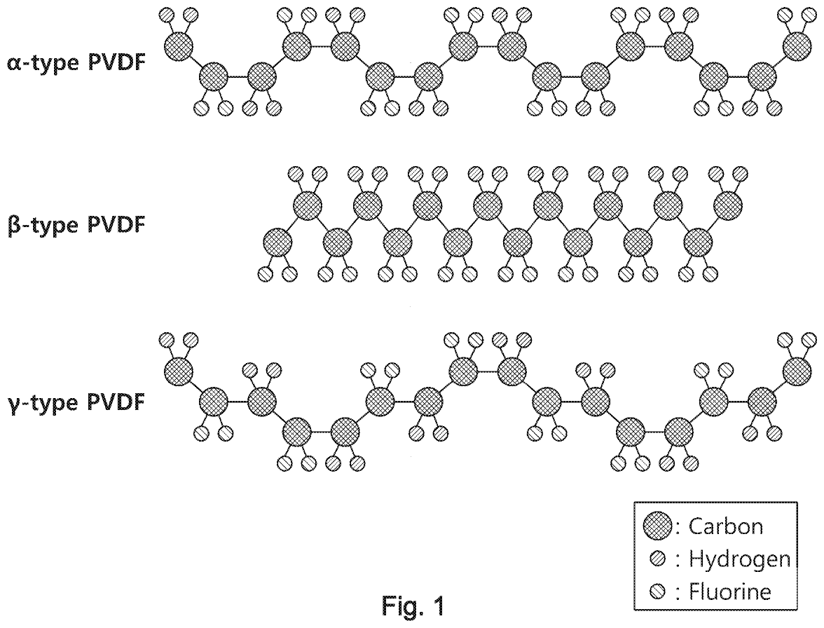

FIG. 2 shows schematically an electrospinning process for production of polyvinylidene fluoride (PVDF)-based composite nanofiber membranes according to an embodiment of the present disclosure.

FIG. 3 shows the structure and a photographic image of a piezoelectric device with the polyvinylidene fluoride (PVDF)-based composite nanofiber membrane according to an embodiment of the present disclosure.

FIG. 4 shows a photographic image of a tester for the piezoelectric device according to an embodiment of the present disclosure.

FIG. 5 shows SEM images of PVDF ((a) & (b)), PVDF/PDMS1 ((c) & (d)) and PVDF/PDMS2 ((e) & (f)) nanofiber membranes according to an embodiment of the present disclosure.

FIG. 6 shows average diameters of PVDF, PVDF/PDMS1 and PVDF/PDMS2 nanofibers according to an embodiment of the present disclosure.

FIG. 7 shows stress-strain curves of PVDF, PVDF/PDMS1 and PVDF/PDMS2 nanofiber membranes according to an embodiment of the present disclosure.

FIG. 8 shows water contact angles of PVDF and PVDF/PDMS2 nanofiber membranes according to an embodiment of the present disclosure.

FIG. 9 shows SEM images of PVDF ((a) & (b)), PVDF/AgNPs ((c) & (d)) and PVDF/PDMS/AgNPs ((e) & (f)) nanofiber membranes according to an embodiment of the present disclosure.

FIG. 10 shows stress-strain curves of PVDF, PVDF/PDMS2, PVDF/AgNPs and PVDF/PDMS/AgNPs nanofiber membranes according to an embodiment of the present disclosure.

FIG. 11 shows SEM images of PVDF ((a) & (b)), PVDF/MXene ((c) & (d)) and PVDF/PDMS/MXene ((e) & (f)) nanofiber membranes according to an embodiment of the present disclosure.

FIG. 12 shows stress-strain curves of PVDF, PVDF/PDMS2, PVDF/MXene and PVDF/PDMS/MXene nanofiber membranes according to an embodiment of the present disclosure.

FIG. 13 shows output voltages of PVDF, PVDF/PDMS2, PVDF/AgNPs and PVDF/PDMS/AgNPs nanofiber membranes according to an embodiment of the present disclosure at 10 Hz.

FIG. 14 shows output voltages of PVDF/PDMS/AgNPs nanofiber membranes according to an embodiment of the present disclosure at various frequencies.

FIG. 15 shows output voltages of PVDF/PDMS/AgNPs nanofiber membranes according to an embodiment of the present disclosure at 8 Hz over 15,000 cycles.

FIG. 16 shows output voltages of PVDF, PVDF/PDMS2, PVDF/MXene and PVDF/PDMS/MXene nanofiber membranes according to an embodiment of the present disclosure at 10 Hz.

FIG. 17 shows output voltages of PVDF/PDMS/MXene nanofiber membranes according to an embodiment of the present disclosure at various frequencies.

FIG. 18 shows output voltages of PVDF/PDMS/MXene nanofiber membranes according to an embodiment of the present disclosure at 8 Hz over 15,000 cycles.

### DETAILED DESCRIPTION

Hereinafter, the present disclosure will be described in detail. The terms or words used in the specification and the appended claims should not be construed as being limited to general and dictionary meanings, and should be interpreted based on the meanings and concepts corresponding to the technical aspects of the present disclosure on the basis of the principle that the inventor is allowed to define terms appropriately for the best explanation.

To achieve the above-described objectives, the present disclosure provides composite nanofiber membrane comprising nanofibers comprising a fluorine-based polymer and a crosslinked product of a siloxane-based polymer precursor; and a conductive nanomaterial dispersed in the nanofibers.

According to an embodiment of the present disclosure, the fluorine-based polymer may include at least one selected from polyvinylidene fluoride (PVDF), polytetrafluoroethylene (PTFE) or polyvinylidene fluoride-co-hexafluoropropylene (PVDF-co-HFP), and more preferably, the fluorine-based polymer may include β-phase polyvinylidene fluoride (PVDF) having piezoelectricity.

According to an embodiment of the present disclosure, the conductive nanomaterial may include at least one selected from silver nanoparticles (AgNPs) or MXene.

According to an embodiment of the present disclosure, the nanofibers may be produced through electrospinning, and the siloxane-based polymer precursor is cross-linked using a curing agent before the electrospinning.

More specifically, the crosslinking reaction of the siloxane-based polymer precursor may be a crosslinking reaction between compounds as shown in the following reaction formula 1.

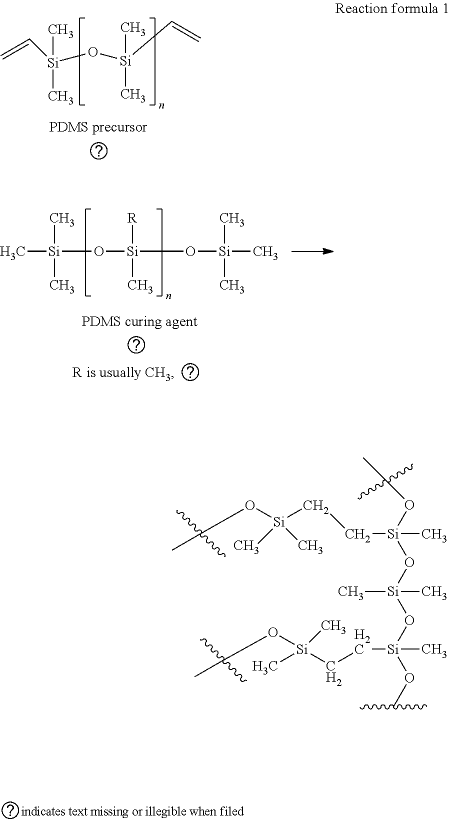

In addition, the present disclosure provides a piezoelectric device including the composite nanofiber membrane.

The piezoelectric device according to an embodiment of the present disclosure may be a sandwich-structured piezoelectric device having a protective layer of polyimide (PI) film after electrospinning of the composite nanofiber membrane on a copper plate, and more specifically, may be a PI-electrode-membrane-electrode-PI sandwich-structured piezoelectric device, and in this instance, the composite nanofiber membrane preferably have a thickness of 100 μm to 200 μm.

In addition, the present disclosure provides a method for manufacturing the composite nanofiber membrane, including the steps of: preparing a mixture solution of the fluorine-based polymer and the siloxane-based polymer precursor; dispersing the conductive nanomaterial in the mixture solution; crosslinking the siloxane-based polymer precursor in the mixture solution containing the dispersed conductive nanomaterial; and electrospinning the mixture solution containing the crosslinked siloxane-based polymer precursor.

According to an embodiment of the present disclosure, the fluorine-based polymer may include β-phase polyvinylidene fluoride (PVDF) having piezoelectricity, and the conductive nanomaterial may include at least one selected from silver nanoparticles (AgNPs) or MXene.

Hereinafter, embodiments and examples of the present disclosure will be described in detail with reference to the accompanying drawings to enable those having ordinary skill in the technical field pertaining to the present disclosure to easily practice the present disclosure. In particular, the technical aspects of the present disclosure, the key components and operation are not limited thereto. Furthermore, the present disclosure may be embodied in many different forms and is not limited to the embodiments and examples described herein.

### Preparation Example 1: Preparation of PVDF/PDMS Nanofiber Membrane

All reagents and chemicals used in the present disclosure were obtained commercially. PVDF (FL-2606, Mw=350,000~440,000, pellet), PDMS precursor (Sylgard 184 A) and a curing agent (Sylgard 184 B) were used. In addition, N-dimethylformamide (DMF) and tetrahydrofuran (THF) were used as solvents.

The PVDF/PDMS nanofiber membrane according to an embodiment of the present disclosure was prepared by the following method. First, 17% (w/v) of PVDF pellets were dissolved in DMF and THE at a 6:4 ratio, and stirred using a stirrer at 300 rpm for 6 to 12 hours at room temperature. At the same time, Sylgard 184 A was dissolved in THF. In this instance, PVDF/PDMS1 refers to a 6:1 ratio of PVDF to PDMS on the weight-to-volume basis, and PVDF/PDMS2 refers to a 3:1 ratio of PVDF to PDMS on the weight-to-volume basis. Sylgard 184 A was stirred with THE in a shaker at room temperature for 6 to 12 hours, and the PVDF solution and the Sylgard A solution were mixed and sonicated in an ultrasonic bath sonicator for 90 minutes or longer. According to the Sylgard 184 manual, Sylgard 184 B was added to the solution at a ratio of 10:1 relative to Sylgard A and stirred at room temperature for 2 days. After curing, in an electrospinning machine (ER100, Nanonc, Korea), the solution was loaded into a 10 mL syringe and placed on a syringe pump, and fibers were collected from a collector wrapped with a steel plate. In this instance, preferably, the flow rate is 1 to 3 mL/h, the tip-to-collector distance (TCD) is 15 to 20 cm, and the voltage is 15 to 25 kV.

### Preparation Example 2: Preparation of PVDF/PDMS/AgNPs Nanofiber Membrane

The PVDF/PDMS/AgNPs nanofiber membrane according to an embodiment of the present disclosure was prepared by the following method. All processes were similar to PVDF/PDMS preparation of Preparation Example 1. Before adding Sylgard B, 1% (w/v) of AgNPs (US-1028, US Research Nanomaterials, Inc) was dispersed in DMF and sonicated with PVDF/Sylgard A solution, and the two solutions were stirred and sonicated for 90 minutes. After sonication, Sylgard B was added to the solution and stirred at room temperature for 2 days, and after curing, the PVDF/PDMS/AgNPs solution was electrospun in the same flow rate, TCD and voltage conditions

### Preparation Example 3: Preparation of PVDF/PDMS/MXene Nanofiber Membrane

The PVDF/PDMS/MXene nanofiber membrane according to an embodiment of the present disclosure was prepared by the following method. All processes were the same as those used in PVDF/PDMS/AgNPs preparation of Preparation Example 2. In the PVDF/PDMS/MXene solution, 1% (w/v) of MXene (12363-89-2, TMALAB) was used instead of AgNPs.

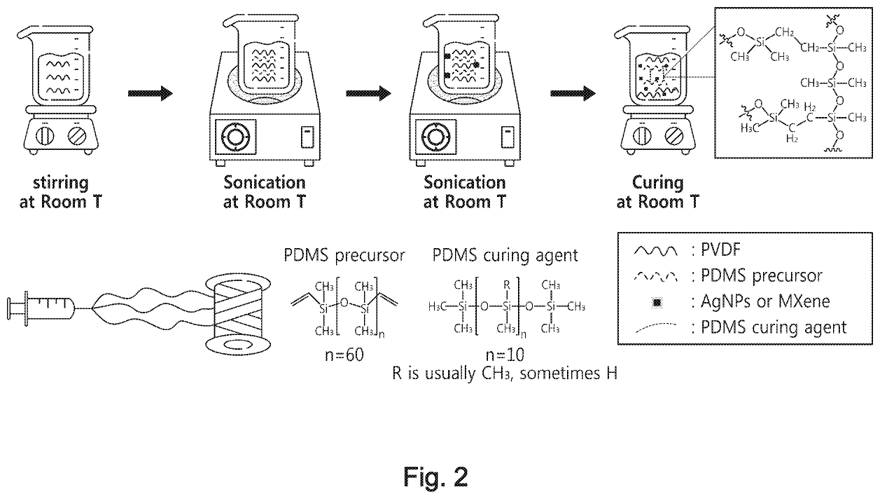

FIG. 2 shows schematically the electrospinning process for production of the polyvinylidene fluoride (PVDF)-based composite nanofiber membranes according to an embodiment of the present disclosure, and TABLE 1 below summarizes the composition according to each preparation example.

TABLE 1

| | PVDF | PDMS | AgNPs | MXene |
|---|---|---|---|---|
| Sample | (wt %) | (wt %) | (wt %) | (wt %) |
| PVDF | 17 | — | — | — |
| PVDF/PDMS1 | 17 | 2.8 | — | — |
| PVDF/PDMS2 | 17 | 5.7 | — | — |
| PVDF/AgNPs | 17 | — | 1 | — |
| PVDF/PDMS/AgNPs | 17 | 5.7 | 1 | — |
| PVDF/MXene | 17 | — | — | 1 |
| PVDF/PDMS/MXene | 17 | 5.7 | — | 1 |

### Preparation Example 4: Preparation of PVDF/PDMS Nanofiber Membrane Piezoelectric Device

The PVDF/PDMS nanofiber membrane piezoelectric device according to an embodiment of the present disclosure was prepared by the following method. The solution was electrospun to a copper plate (50 μm). The membrane was cut into 5×5 cm², attached to another copper plate and covered with a PI film to manufacture a PI-electrode-membrane-electrode-PI sandwich-structured piezoelectric device.

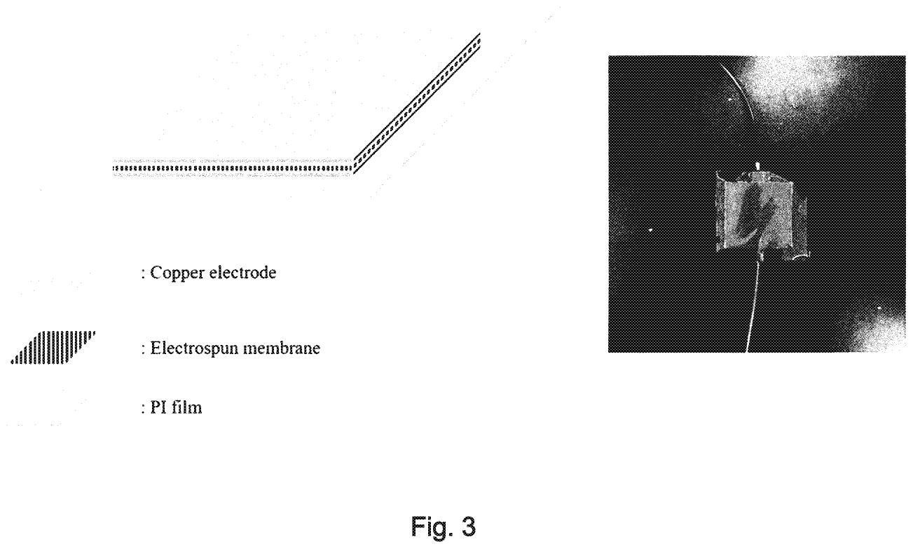

FIG. 3 shows the structure and a photographic image of the piezoelectric device with the polyvinylidene fluoride (PVDF)-based composite nanofiber membrane according to an embodiment of the present disclosure.

### Analysis Example

Analysis of the structures or properties of the polyvinylidene fluoride (PVDF)-based composite nanofiber membranes according to an embodiment of the present disclosure was conducted by the following method.

The morphology of each nanofiber membrane, its average diameter and the presence of nanoparticles inside were analyzed using Field Emission Scanning Electron Microscopy (FE-SEM) (SU8230, Hitachi, Japan) and Biological (low-voltage) Transmission Electron Microscopy (Bio-TEM) (HT 7700, Hitachi, Japan).

PVDF/PDMS was analyzed using Fourier transform infrared spectroscopy (FT-IR), and the mechanical strength of all the nanofiber membranes was analyzed using a universal testing machine (UTM) for each sample which is 6 cm in length and 1 cm in width. The average values of five measurements of all the samples were plotted on stress-strain curves.

The water resistance test was conducted using a Drop Shape Analyzer. Each measurement result was recorded according to standardized procedures, and the average values were calculated five times. The phase of PVDF and the spectrum of each nanoparticle were analyzed using X-ray diffraction.

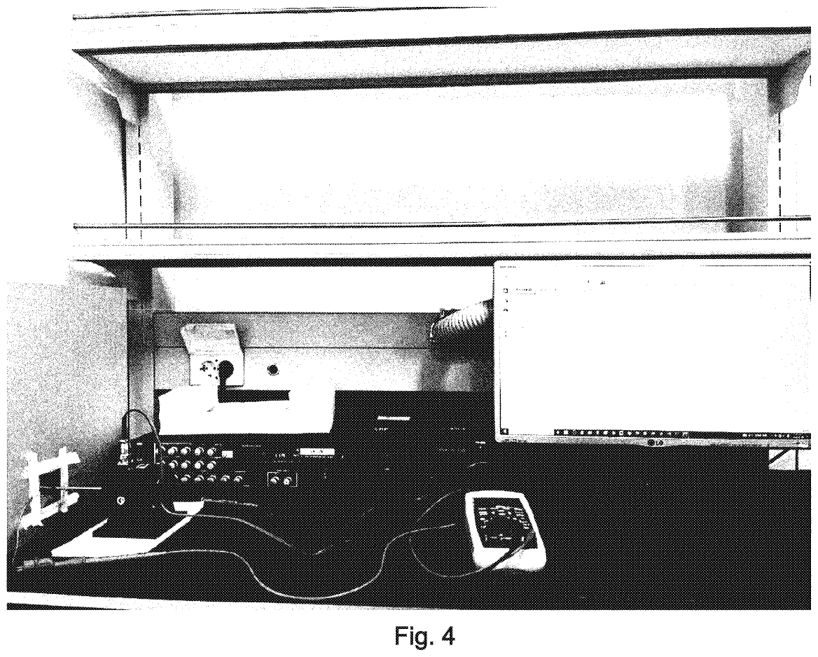

The properties of the piezoelectric device were analyzed by applying a mechanical external force to the device using a mini shaker (MS-20), and providing a signal to the mini shaker using a power amplifier and a function generator. During operation of MS-20, voltage was measured by a digital multimeter (Fluke 289, Fluke, USA) connected to Fluke PC program. FIG. 4 shows a photographic image of the tester for the piezoelectric device according to an embodiment of the present disclosure.

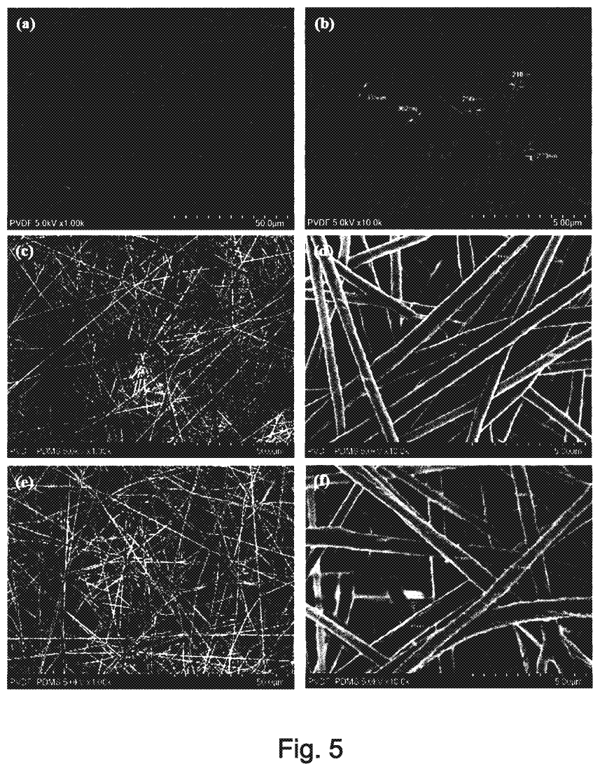

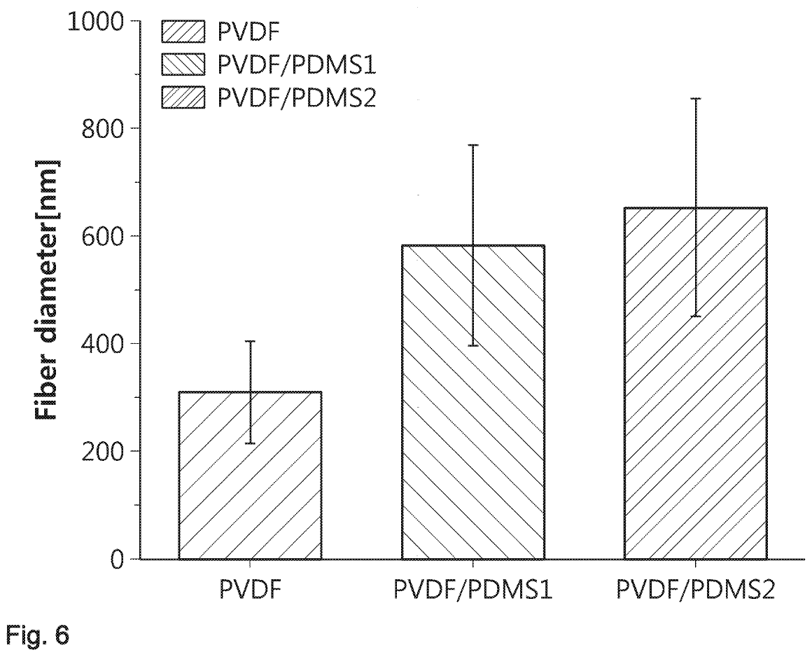

FIG. 5 shows SEM images of PVDF ((a) & (b)), PVDF/PDMS1 ((c) & (d)) and PVDF/PDMS2 ((e) & (f)) nanofiber membranes according to an embodiment of the present disclosure. As can be seen from FIG. 5, no beads were observed in the samples of the nanofiber membranes. In addition, FIG. 6 shows average diameters of the PVDF, PVDF/PDMS1 and PVDF/PDMS2 nanofiber membranes according to an embodiment of the present disclosure. 30 diameters of each sample were randomly collected and the average of nanofiber diameters was calculated. The average fiber diameter was 310.77+96.02 nm for PVDF, 581.73+184.13 nm for PVDF/PDMS1, and 654.6=202.35 nm for PVDF/PDMS2 nanofiber membranes. In the case of PVDF/PDMS, the average fiber diameter tends to increase by 250 to 350 nm or more, driven by curing at the same time as adding PDMS.

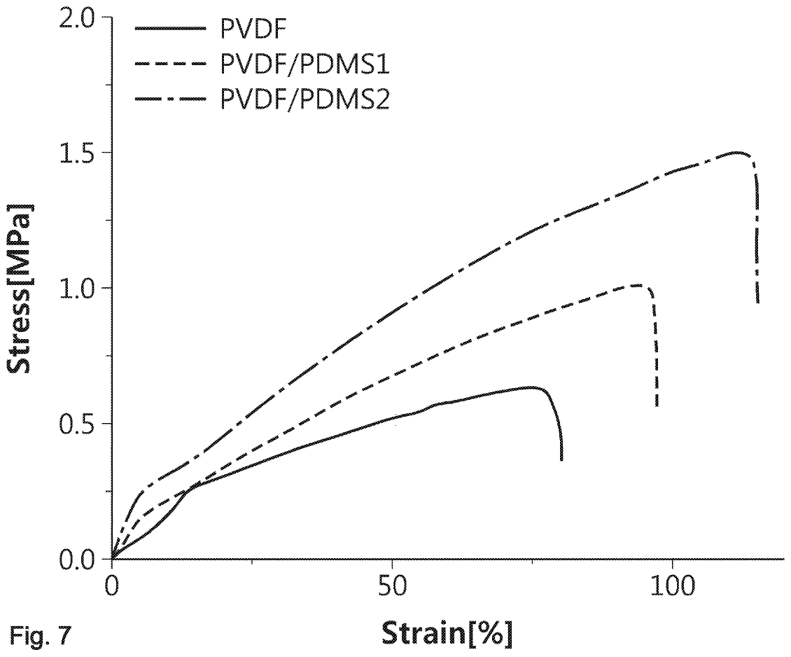

FIG. 7 shows stress-strain curves of the PVDF, PVDF/PDMS1 and PVDF/PDMS2 nanofiber membranes according to an embodiment of the present disclosure.

The mechanical strength of the PVDF composite nanofiber membrane was determined using UTM according to an embodiment of the present disclosure. With the increasing amount of PDMS in the nanofiber membrane, flexibility increased, and strength increased due to the crosslinking of PDMS. As a result, because PVDF/PDMS2 has higher strength and flexibility than PVDF/PDMS1, PVDF/PDMS2 may be more desirable in the subsequent addition of conductive nanoparticles.

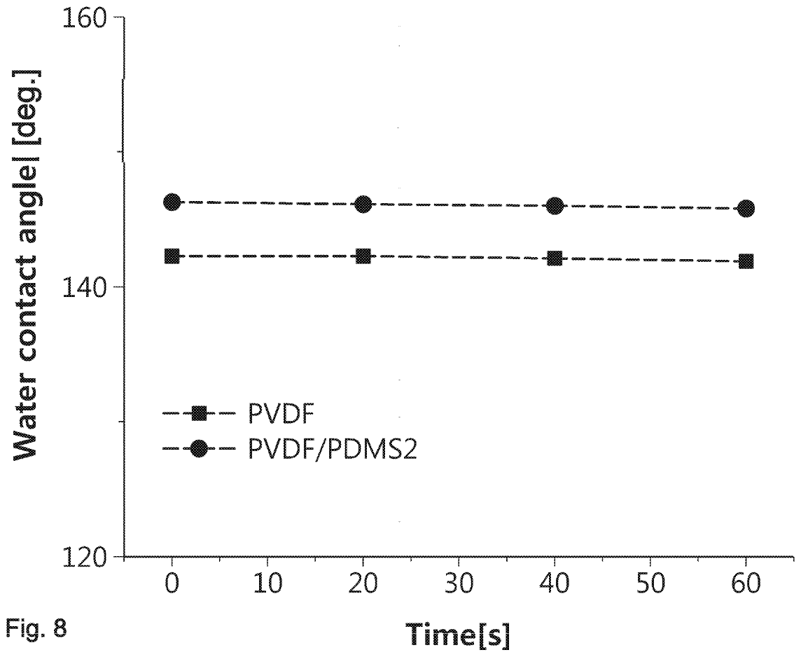

FIG. 8 shows water contact angles of the PVDF and PVDF/PDMS2 nanofiber membranes according to an embodiment of the present disclosure.

As can be seen from FIG. 8, it can be seen that the PVDF/PDMS2 nanofiber membrane has the water contact angle (146.2° to) 145.8° that is about 4° higher than the PVDF nanofiber membrane (142.2° to) 141.9°, and thus, has improved hydrophobicity.

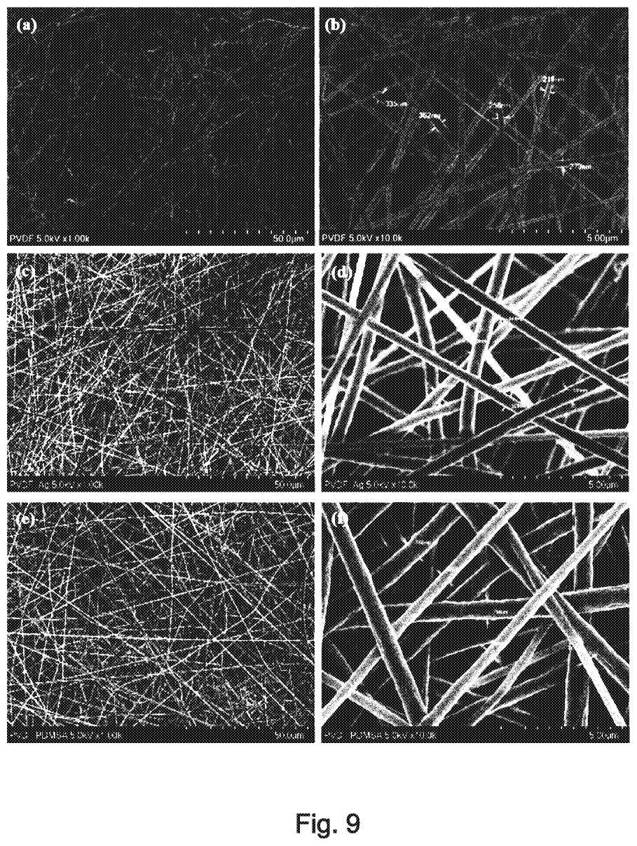

FIG. 9 shows SEM images of the PVDF ((a) & (b)), PVDF/AgNPs ((c) & (d)) and PVDF/PDMS/AgNPs ((e) & (f)) nanofiber membranes according to an embodiment of the present disclosure, showing that the AgNPs appear to be dispersed in the nanofibers without forming aggregates on the surface.

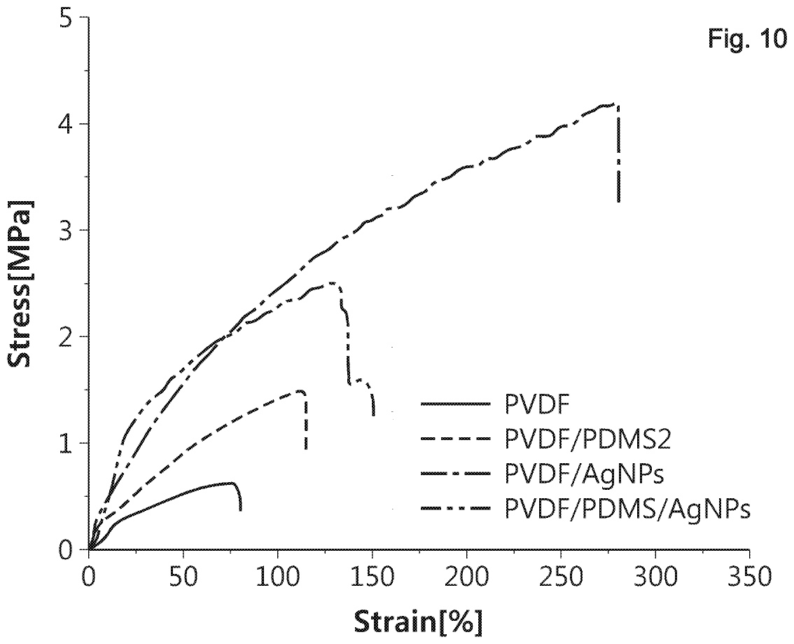

FIG. 10 shows stress-strain curves of the PVDF, PVDF/PDMS2, PVDF/AgNPs and PVDF/PDMS/AgNPs nanofiber membranes according to an embodiment of the present disclosure.

The addition of AgNPs to PVDF increases the mechanical strength and flexibility, compared to neat PVDF and PVDF/PDMS2 nanofiber membranes, and this signifies that AgNPs may act as a reinforcement in the nanofiber membranes.

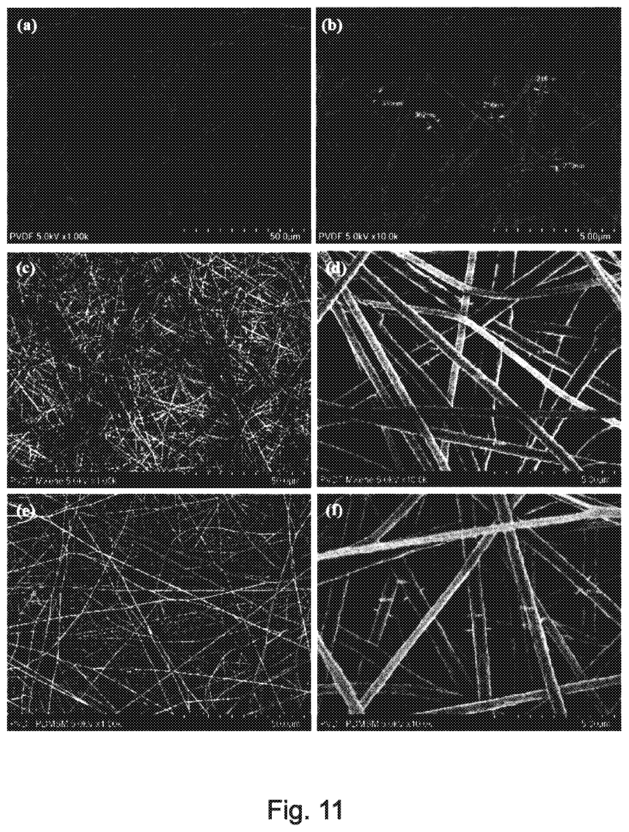

FIG. 11 shows SEM images of the PVDF ((a) & (b)), PVDF/MXene ((c) & (d)) and PVDF/PDMS/MXene ((e) & (f)) nanofiber membranes according to an embodiment of the present disclosure, showing that MXene appear to be dispersed in the nanofibers without forming aggregates on the surface.

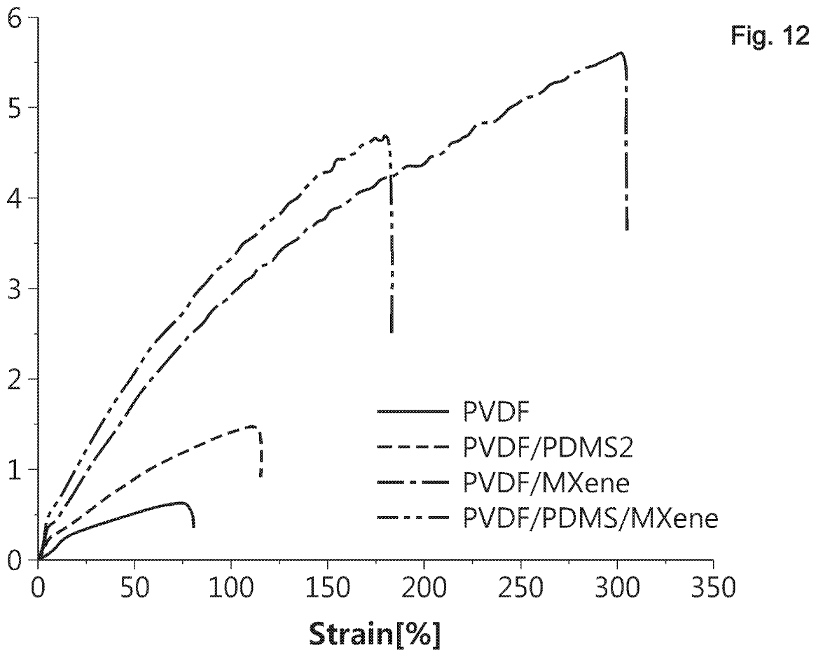

FIG. 12 shows stress-strain curves of the PVDF, PVDF/PDMS2, PVDF/MXene and PVDF/PDMS/MXene nanofiber membranes according to an embodiment of the present disclosure.

As shown in FIG. 10, the PVDF/PDMS/MXene nanofiber membrane has higher mechanical strength and flexibility than PVDF and PVDF/PDMS2 nanofiber membrane due to the addition of MXene to PDMS. Furthermore, the PVDF/PDMS/MXene nanofiber membrane has similar Young's modulus to the PVDF/MXene nanofiber membrane, but lower flexibility due to the lack of synergistic effect of MXene and PDMS.

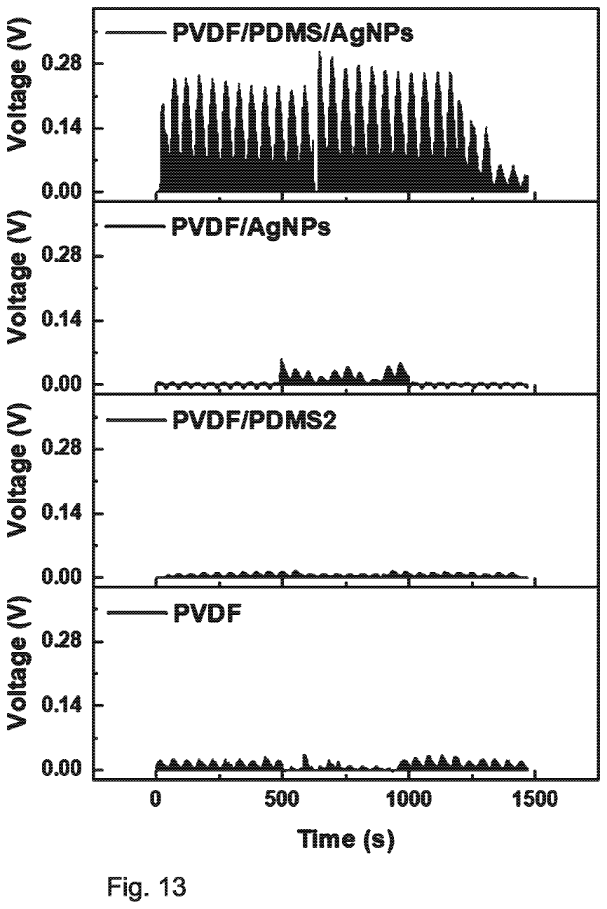

FIG. 13 shows output voltages of the PVDF, PVDF/PDMS2, PVDF/AgNPs and PVDF/PDMS/AgNPs nanofiber membranes according to an embodiment of the present disclosure at 10 Hz.

A piezoelectric experiment was performed by applying pressure to multiple points of the PVDF composite nanofiber membrane device and measuring responses. The PVDF/PDMS/AgNPs nanofiber membrane shows piezoelectric responses that are 2-3 times higher than the PVDF nanofiber membrane. Furthermore, the addition of PDMS drives uniform piezoelectric responses, and presumably, PDMS plays a role in transmitting external stimuli to the surrounding nanofibers, leading to uniform and high piezoelectric responses in PVDF/PDMS/AgNPs.

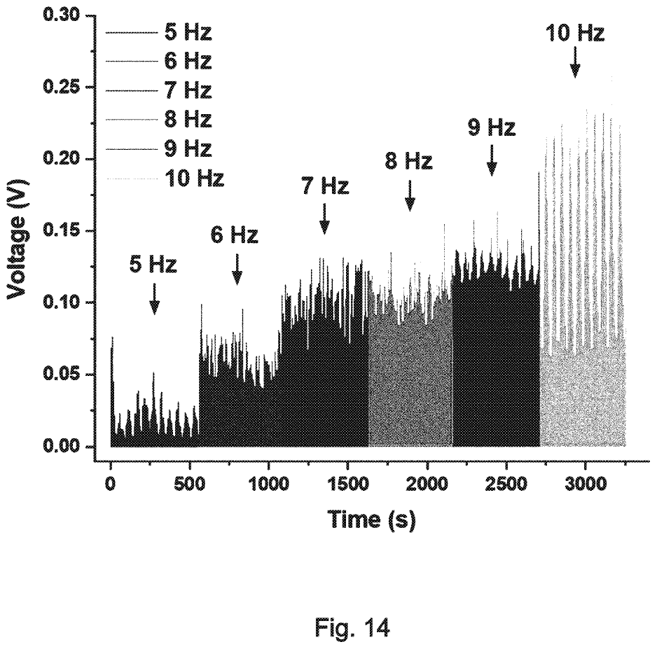

FIG. 14 shows output voltages of the PVDF/PDMS/AgNPs nanofiber membranes according to an embodiment of the present disclosure at various frequencies.

In FIG. 14, the function generator was controlled to measure the piezoelectricity of the PVDF/PDMS/AgNPs nanofiber membrane at various frequencies from 5 Hz to 10 Hz, and as higher mechanical stimuli are applied to the PVDF/PDMS/AgNPs nanofiber membrane, the voltage of the piezoelectric device tends to increase.

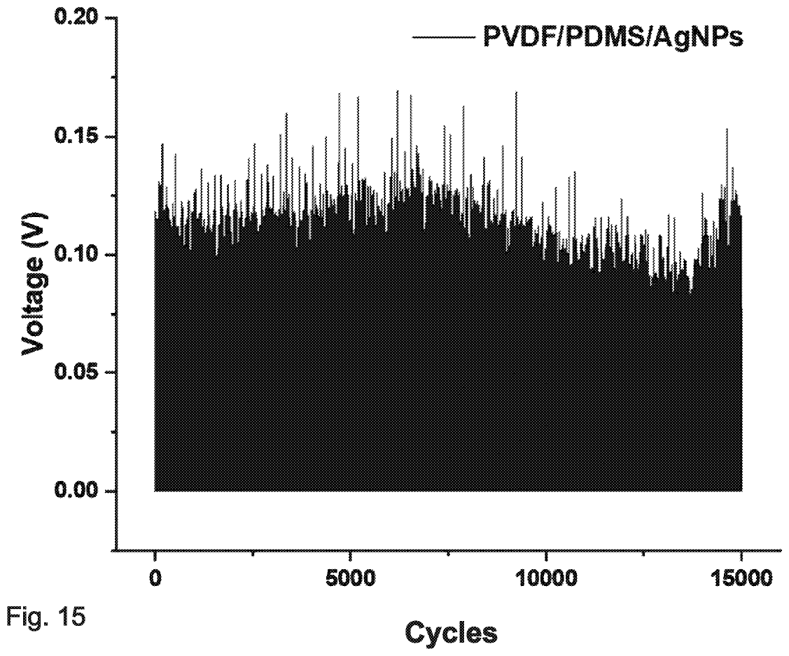

FIG. 15 shows output voltages of the PVDF/PDMS/AgNPs nanofiber membrane according to an embodiment of the present disclosure at 8 Hz over 15,000 cycles. The PVDF/PDMS/AgNPs nanofiber membrane device shows stable performance over 15,000 cycles of stimuli.

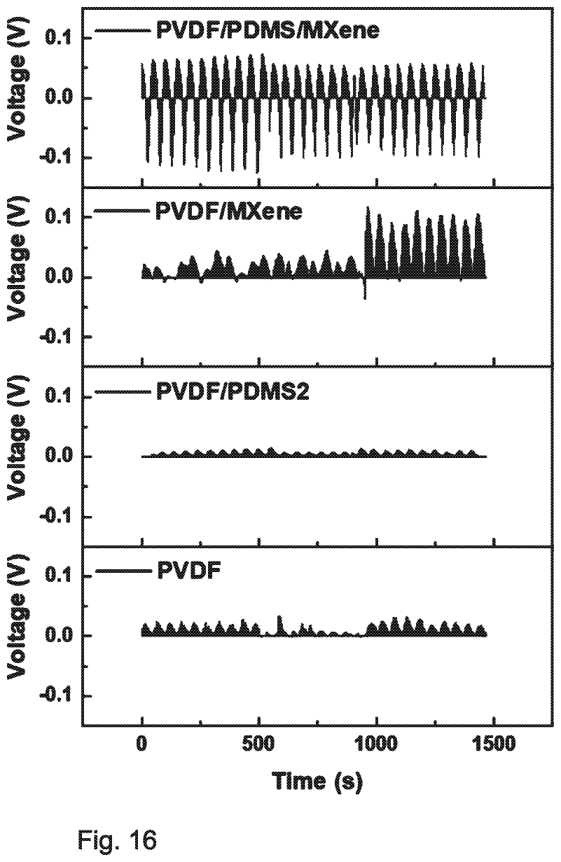

FIG. 16 shows output voltages of the PVDF, PVDF/PDMS2, PVDF/MXene and PVDF/PDMS/MXene nanofiber membranes according to an embodiment of the present disclosure at 10 Hz. The PVDF/PDMS/MXene nanofiber membrane shows piezoelectric responses that are 4-5 times higher than the PVDF nanofiber membrane. Like FIG. 20, the addition of PDMS drives uniform piezoelectric responses, and presumably, piezoelectricity is greatly increased by a synergistic effect with the inherent piezoelectricity of MXene.

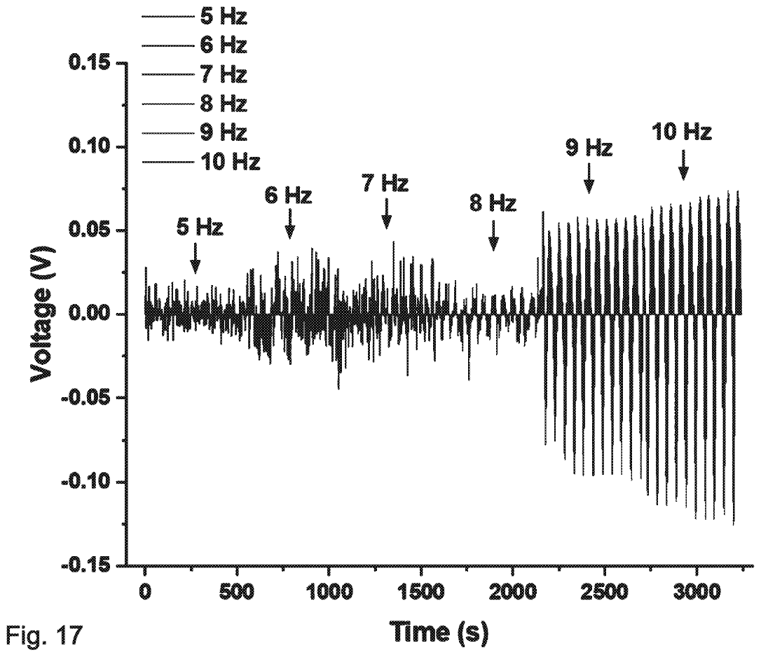

FIG. 17 shows output voltages of the PVDF/PDMS/MXene nanofiber membrane according to an embodiment of the present disclosure at various frequencies. As mechanical stimuli applied to the PVDF/PDMS/MXene nanofiber membrane device are elevated, piezoelectricity tends to increase.

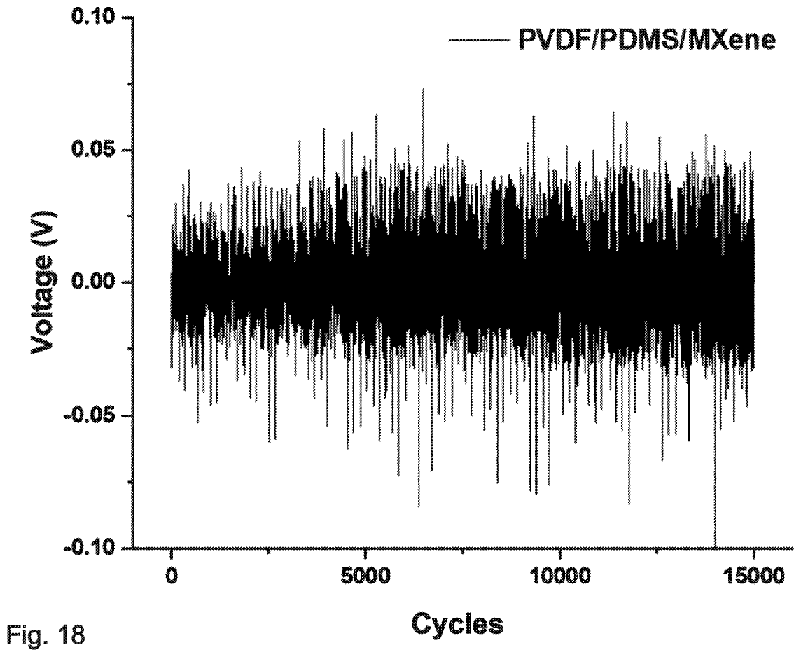

FIG. 18 shows output voltages of the PVDF/PDMS/MXene nanofiber membrane according to an embodiment of the present disclosure at 8 Hz over 15,000 cycles. The PVDF/PDMS/MXene nanofiber membrane device shows stable piezoelectricity over 15,000 cycles of continuous stimuli.

As described above, according to an embodiment of the present disclosure, PVDF/PDMS/AgNPs and PVDF/PDMS/MXene were produced through PVDF combined with AgNPs and MXene, and the morphological, structural, mechanical and piezoelectric properties of the manufactured nanofiber membranes were analyzed. The nanofiber membranes comprising AgNPs and MXene showed high mechanical strength, flexibility and thermal stability, and the piezoelectric performance of the PVDF/PDMS/AgNPs and PVDF/PDMS/MXene nanofiber membranes was more uniform and 3 to 5 times higher than the PVDF nanofiber membrane. In addition, the PVDF composite nanofiber membrane device had higher piezoelectricity with higher mechanical stimuli applied, and showed stable piezoelectricity over 15,000 cycles of stimuli. In conclusion, it is expected that the nanofiber membranes manufactured according to an embodiment of the present disclosure will be a promising material for applications in flexible and wearable devices, medical and biosensors and audio devices as well as filters, vents and touch panels.

The foregoing description of the embodiments of the invention has been presented for the purposes of illustration and description. Each and every page of this submission, and all contents thereon, however characterized, identified, or numbered, is considered a substantive part of this application for all purposes, irrespective of form or placement within the application. This specification is not intended to be exhaustive or to limit the invention to the precise form disclosed. Many modifications and variations are possible in light of this disclosure.

Although the present application is shown in a limited number of forms, the scope of the disclosure is not limited to just these forms, but is amenable to various changes and modifications. The present application does not explicitly recite all possible combinations of features that fall within the scope of the disclosure. The features disclosed herein for the various embodiments can generally be interchanged and combined into any combinations that are not self-contradictory without departing from the scope of the disclosure. In particular, the limitations presented in dependent claims below can be combined with their corresponding independent claims in any number and in any order without departing from the scope of this disclosure, unless the dependent claims are logically incompatible with each other.

What is claimed is:

1. A composite nanofiber membrane comprising:
nanofibers comprising a fluorine-based polymer and a crosslinked product of a siloxane-based polymer precursor; and
a conductive nanomaterial dispersed in the nanofibers.

2. The composite nanofiber membrane according to claim 1, wherein the fluorine-based polymer includes at least one selected from the group consisting of polyvinylidene fluoride (PVDF), polytetrafluoroethylene (PTFE), or polyvinylidene fluoride-co-hexafluoropropylene (PVDF-co-HFP).

3. The composite nanofiber membrane according to claim 1, wherein the fluorine-based polymer includes β-phase polyvinylidene fluoride (PVDF) having piezoelectricity.

4. The composite nanofiber membrane according to claim 1, wherein the conductive nanomaterial includes at least one selected from the group consisting of silver nanoparticles (AgNPs) and MXene.

5. The composite nanofiber membrane according to claim 1, wherein the nanofibers are produced through electrospinning.

6. The composite nanofiber membrane according to claim 5, wherein the crosslinked product is formed by cross-linking the siloxane-based polymer precursor before the electrospinning.

7. A piezoelectric material comprising a composite nanofiber membrane according to claim 1.

8. A method for manufacturing a composite nanofiber membrane, the method comprising the steps of:
preparing a mixture solution of a fluorine-based polymer and a siloxane-based polymer precursor;
dispersing a conductive nanomaterial in the mixture solution;
crosslinking the siloxane-based polymer precursor in the mixture solution containing the dispersed conductive nanomaterial; and
electrospinning the mixture solution containing the crosslinked siloxane-based polymer precursor.

9. The method for manufacturing the composite nanofiber membrane according to claim 8, wherein the fluorine-based polymer includes β-phase polyvinylidene fluoride (PVDF) having piezoelectricity.

10. The method for manufacturing the composite nanofiber membrane according to claim 8, wherein the conductive nanomaterial includes at least one selected from the group consisting of silver nanoparticles (AgNPs) or MXene.
